(19) United States
(12) Patent Application Publication
(10) Pub. No.: US 2010/0108988 A1
(43) Pub. Date: May 6, 2010

(54) Nanotube-Based Structure and Method of Forming the Structure

(75) Inventors: Haim Grebel, Livingston, NJ (US); David Katz, Modiin (IL); Seon Woo Lee, Palisades Park, NJ (US)

Correspondence Address: NEW JERSEY INSTITUTE OF TECHNOLOGY, 323 MARTIN LUTHER KING, JR. BOULEVARD, OFFICE OF RESEARCH AND DEVELOPMENT, NEWARK, NJ, 07102-1982, US

(73) Assignee: New Jersey Institute of Technology, Newark, NJ (US)

(21) Appl. No.: 12/201,530

(22) Filed: Aug. 29, 2008

Related U.S. Application Data
(60) Provisional application No. 60/968,767, filed on Aug. 29, 2007.

(51) Int. Cl. H01L 29/66; H01B 5/00; H01R 43/00

(52) U.S. Cl. 257/24; 174/126.1; 174/126.2; 29/825; 257/E29.168; 977/938; 977/742

(57) ABSTRACT

Nanotube-based structure and method of forming the same are disclosed. A structure having two tips is provided for defining a location for forming a nanotube connection. The nanotube connection, which can be coated with an electrically conductive polymer for enhanced conductivity, can be used in forming nanotube-based devices for various applications.

### CROSS-REFERENCE TO RELATED APPLICATIONS

The present application claims the benefit of a co-pending, commonly assigned provisional patent application entitled “Nanotube-Based Structure and Method of Forming the Structure,” which was filed on Aug. 29, 2007 and assigned Ser. No. 60/968,767.

### FIELD OF THE INVENTION

The present invention generally relates to nanotube-based structure and method of forming such a structure.

### BACKGROUND OF THE INVENTION

Carbon nanotubes (CNT) have unique electrical, optical and mechanical properties, and have been used as active elements or electrical connections in various devices. Connections formed by CNTs, e.g., between metal electrodes, have been shown to exhibit various phenomena including single electron transport, photodesorption, and electroluminescence, among others. CNT-based connections have also been used in devices such as a room temperature single electron transistor or CNT field-effect transistor (CNT FET). These connections are often intra-layer connections provided on the surface of a material layer or within a layer. These intraconnects are sometimes referred to as bridges. In multilayered circuit design, inter-layer connections are also provided that span across different layers, e.g., in a vertical direction or perpendicular to the layer's surface. Since many interconnect applications require larger currents and larger vias compared to intraconnects, CNT bundles are often used.

In most intra-connect fabrication methods, CNTs are randomly dispersed on pre-defined contacts, e.g., Postma et al., Science, vol. 293, 76-79 (2001) and Tans et al., Nature, vol. 393, 49-52 (1998). In many cases, post-processing is also needed after the formation of the intra-connects. Other techniques are based on random CNT growth between periodic structures such as pads or lines, e.g., Soh et al., Appl. Phys. Lett., vol. 75, 627-629 (1999) and Peng et al., Appl. Phys. Lett., vol 83, 4238-4240 (2003). More directional techniques may use catalytic chemical vapor deposition (CVD) at a relatively high temperature, e.g., with methane/hydrogen mixture and hot filaments, as discussed in Marty et al., Nano Lett., vol. 3, 1115-1118 (2003) and Marty et al., Thin Solid Film, vol. 501, 299-302 (2006), or connecting line edges by random shape multi-walled CNTs (MWCNT), e.g., Wei et al., Appl. Phys. Lett., vol 76, 3759-3761 (2000).

One of the factors affecting catalytic growth of CNTs is the catalyst film thickness. Very thin catalytic layers with a thickness between 0.2 to 2 nm have been used to activate the growth of single-walled CNT via CVD, e.g., Peng et al., Appl. Phys. Lett., vol 83, 4238-4240 (2003). It is believed that the use of thin catalytic films allows the growth temperature to be reduced to 600° C., e.g., Seidel et al., J. Phys. Chem., vol. 108, 1888-1893 (2004), Liao et al., J. Phys. Chem., vol. B108, 6941 (2004), and Li et al., Nano Lett., vol. 4, 317-321 (2004). Thicker catalyst layers typically result in the growth of MWCNTs. Another factor is the concentration of carbon source or precursor. For example, it is known that CNT growth yield may be enhanced by adding hydrogen to carbon monoxide precursor during deposition, e.g., Bladh et al., Appl. Phys. A: Mater. Sci. Process, vol. 70, 317-322 (2000), Zheng et al., Nano Lett. vol. 2, 895-898 (2002), and Nolan et al., J. Phys. Chem. B vol. 102, 4165-4175 (1998).

Despite numerous studies relating to nanotube growth, there is as yet no report of controllable nanotube growth, in which an individual CNT connection can be formed between two predetermined locations with nanoscale precision.

### SUMMARY OF INVENTION

Embodiments of the present invention provide for various nanotube-based structure and method of fabricating the struture.

In one embodiment, a structure includes two conductive tapered members each having a tip with a radius of curvature less than about 20 nm, and the two tips are separated by a distance of less than about 1500 nm.

Another embodiment provides a method of forming a nanotube-based structure that includes providing two conductive tapered members each having a tip, and forming a nanotube connection between the two tips.

Another embodiment provides a nanotube-based structure that includes: a first conductive tapered member having a first tip, a second conductive tapered member having a second tip, a nanotube having a first end attached to the first tip and a second end attached to the second tip, in which the first and second tips each has a radius of curvature of less than about 20 nm.

Yet another embodiment provides a nanotube-based device that includes: a first conductive tapered member having a first tip, a second conductive tapered member having a second tip, a nanotube connection between the first and second tips, a dielectric, and a conductive layer separated from the nanotube connection by the dielectric.

### BRIEF DESCRIPTIONS OF THE FIGURES

The teachings of the present invention can be readily understood by considering the following detailed description in conjunction with the accompanying drawings, in which:

FIG. 1A is a schematic illustration of a top view of one embodiment of a structure for defining a location for nanotube formation;

FIG. 1B is an image of a structure obtained by scanning electron microscope;

FIG. 2 is a schematic illustration of a cross-sectional view of the structure of FIG. 1;

FIG. 3 is a schematic illustration of an apparatus for forming nanotubes using chemical vapor deposition;

FIG. 4A is a schematic illustration of a cross-sectional view of a structure during chemical vapor deposition;

FIG. 4B is a schematic illustration of a cross-sectional view of the formation of a nanotube connection;

FIG. 4C is a schematic illustration of an expanded top view of an area around a tip;

FIG. 5 shows a current-voltage (I-V) measurement of a CVD-grown carbon nanotube connection;

FIG. 6 is a schematic illustration of an apparatus for forming nanotubes using plasma-enhanced chemical vapor deposition;

FIGS. 7A-B shows Raman spectra of carbon nanotubes grown from plasma enhanced chemical vapor deposition with ethanol precursor;

FIGS. 8A-B show Raman spectra of of carbon nanotubes grown from plasma enhanced chemical vapor deposition with a mixture of carbon monoxide and hydrogen;

FIG. 9 is a schematic illustration of an electrochemical cell suitable for coating a carbon nanotube with an electro-conductive polymer;

FIG. 10 shows the Raman spectra obtained for several samples corresponding to carbon nanotube bridges, polypyrrole, and carbon nanotube bridges with polypyrrole;

FIG. 11 shows a current-voltage (I-V) characteristics before and after the formation of CNT-ECP bridges;

FIG. 12A is a schematic illustration of a CNT field effect transistor (FET) according to one embodiment of the present invention;

FIG. 12B is a schematic illustration of an alternative embodiment of a CNT FET;

FIG. 13 shows a current-voltage characteristic of an as-grown CNT intra-connect;

FIG. 14 shows a current-voltage characteristics for a CNT-PPy intra-connect; and

FIG. 15 shows the current-voltage characteristics of a CNT-PPy intra-connect with two different PPy thickness.

To facilitate understanding, identical reference numerals have been used, where possible, to designate identical elements that are common to the figures.

### DETAILED DESCRIPTION

Embodiments of the present invention generally relate to various structures for nanotube-based devices and method of forming the structures. The method allows a controllable growth of nanotube connections at pre-determined locations. For example, embodiments of the present invention allow CNT bridges to be formed with known types of CNT (single-walled or multi-walled) between two pre-determined conductive points with a certain yield of success.

In one embodiment, a structure is provided for defining a location for forming a nanotube connection. The structure includes two tapered members having respective tips, with each tip defining a surrounding area for the formation of a nanotube connection. In another embodiment, the structure includes a carbon nanotube (CNT) connection formed between the two tips. The structure can be formed, for example, by using each tip and its surrounding area as a pre-defined catalytic location for CNT growth using chemical vapor deposition (CVD). The structure may find applications in optoelectronic switches, transistor devices, a variety of sensors on the nano-scale including radiation, chemical and biological sensors. For example, such a structure can be used in forming a field effect transistor (FET) or a chemical or bio-sensor. In yet another embodiment, the nanotube connection is coated with an electrically conductive polymer, which provides enhanced properties and performance of the resulting nanotube connection.

As used herein, an intra-connect or a bridge is generally used to refer to a structure that connects two points within a device, in which the connecting structure lies in a plane of the device. An inter-connect generally refers to a structure connecting two points between two devices, or between different material layers of a device, in which the connecting structure is in a vertical direction to the plane of the device.

Although the examples used in this discussion relate primarily to carbon nanotube intra-connects (or bridges), it is understood that embodiments of the invention can also be adapted to nanotube inter-connects, or connections in general.

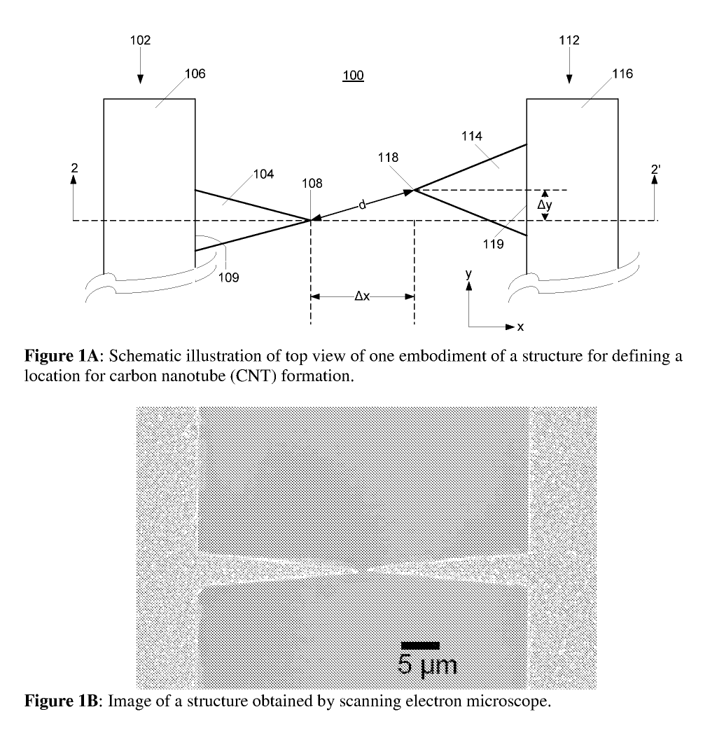

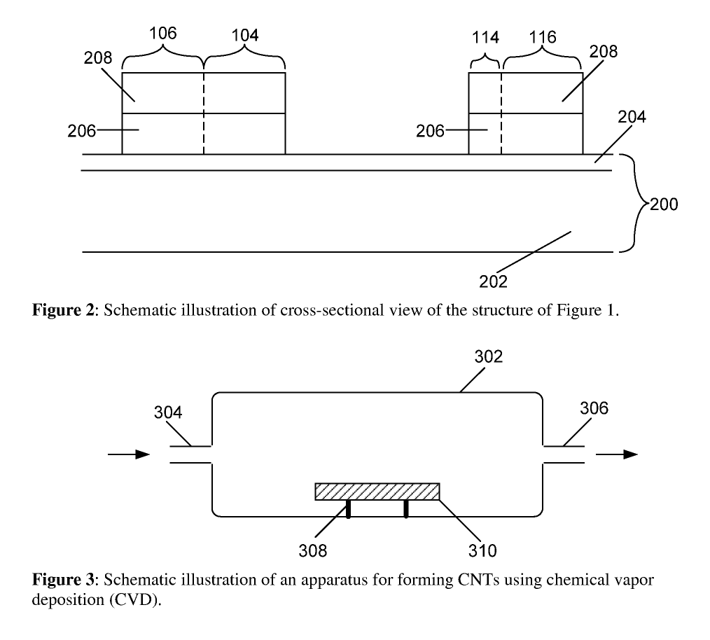

In fabricating a nanotube-based device, the present invention provides a structure to define a location for the formation of a nanotube connection. FIG. 1A is a schematic illustration of a top view of such a structure 100. The structure 100 includes two conductive members 102, 112 (also referred to as electrodes), each containing a tapered member or portion 104, 114. The tapered members 104, 114 have respective tips 108, 118 and base regions 109, 119. In the example of FIG. 1, each tapered member 104, 114 is attached to a respective pad 106, 116 of the conductive members 102, 112. FIG. 1B shows an image of such a structure obtained by scanning electron microscopy.

In general, the conductive members 102, 112 may have configurations different from those shown in FIG. 1A, including one in which the conductive members 102, 112 are the same as the tapered members 104, 114. Alternatively, the two tapered members 104, 114 may have different dimensions or shapes compared to each other, as long as each member includes a tip that is sufficiently sharp or small for defining a location for CNT formation. In addition, the tapered tips may be positioned either with their longitudinal axes being parallel to each other, or intersecting each other at a certain point between the conductive members 102, 112.

The tips 108, 118 are generally separated by a distance Ax along a first direction, e.g., x-direction, and separated by a distance Ay along a second direction, e.g., y-direction. The x- and y-directions are perpendicular, or orthogonal, to each other. Alternatively, the tips 108, 118 may also be characterized by a separation d, which is a direct distance between the two tips. Although controlled CNT growth has been observed by the inventors for a tip separation as large as about 30 μm, a smaller distance, e.g., less than about 10 μm, is more appropriate for most device applications. In general, a higher yield is obtained for shorter tip separation, e.g., from about 0.2 to about 2 μm, or more preferably, less than about 1.5 μm. As will be discussed below, these tips 108, 118 are used to define a location for forming a nanotube connection between the two conductive members 102, 112. The distance Δx may range from about 0.2 micron (μm) to about 1 μm, and Ay may range from about 0 μm to about 1 μm. The position at which Δy is about equal to 0 μm is also referred to as being substantially “aligned”, meaning that there is substantially no offset between the tips 108, 118 in the y-direction.

The inventors have investigated the formation of CNT connections between pairs of tips in an existing layout of electrode-tips, in which the tips are separated by Δx between about 0.2 to about 2 μm, and Ay between about 0 to about 1 μm, and the separations are varied in steps of 0.1 μm. Each pair of tips can be addressed or identified by its own separation distances (Δx, Δy).

Results show that CNT connections can be formed across pairs of tips in a controllable fashion (e.g., with a yield between about 15% to about 30%, depending on the electrode tip orientation and separation distance. A higher yield is favored by either a shorter electrode spacing, e.g., at Δx less than about 1 μm, or a substantially aligned electrode tips (e.g., Δy about equal to 0) compared to laterally-shifted electrode tips with non-zero Ay. Once formed, a CNT intra-connect can carry currents in the microampere (μA) range, up to current densities of about 10⁶ A/cm².

In general, the CNT growth tends to occur between locations of the conductive surfaces that are at the closest distal proximity. However, under different circumstances, CNT growth may also occur between locations that are farther apart than the minimum separation. A configuration having a separation distance (d) of about 500 nm and tapered members with longitudinal axes that are parallel to each other tends to yield the best results.

FIG. 2 is a schematic illustration of a cross-sectional view of the structure 100 taken along a line 2-2′ shown in FIG. 1.

The structure 100 has a substrate 200, which may generally be a silicon (Si) substrate. In one embodiment, the substrate 200 includes a highly doped Si wafer 202 with an oxide layer 204 of about 20 nm serving as a buffer layer. A titanium (Ti) layer 206 with a thickness of less than about 30 nm is formed on the substrate 200. In one embodiment, the Ti thickness is about 20 nm. A cobalt (Co) layer 208 with a thickness of between about 20 to about 60 nm, is then formed on the Ti layer 206. In one embodiment, the Co layer 208 has a thickness of about 30 nm. The Ti layer 206, which promotes adhesion of the Co layer 208 to the substrate 200, also serves as a partial electrode for a device under fabrication (since it is also conductive). In certain applications, the Ti layer 206 may be omitted, in which case, an additional conductive material (not shown) should be formed over the Co layer 208 to serve as the electrode. Suitable electrode materials may include gold (Au), aluminum (Al), or copper (Cu), among others. With the Co/Ti combination layer, the use of additional electrode materials over the Co layer is optional.

The structure 100 can be fabricated using advanced pattern transfer techniques, including for example, electron beam (e-beam) or ion beam lithography, which provide a resolution of about 20 nm. For example, after the Ti and Co layers 206, 208 are deposited on the substrate 200, a suitable resist layer is formed over the Co layer 208. The pattern for the structure 100 is then generated in the e-beam resist layer, and transferred to the underlying Co and Ti layers by etching, e.g., using HF and/or lift-off process. With e-beam lithography, the tips 108, 118 can be fabricated with a radius of curvature as small as about 20 nm.

### Formation of CNT Intra-Connect Using CVD

According to one embodiment of the present invention, thermal CVD is used to for forming a CNT connection at the location predetermined by the two conductive tips of structure 100. FIG. 3 shows a schematic view of a CVD apparatus 300 that can be used for forming CNTs. The apparatus 300 includes a quartz tube 302 having at least one inlet 304 for introducing one or more processing gases or precursors. An outlet 306 is also provided for the removal of the processing gases or reaction products. A sample holder 308 is provided inside the quartz tube 302 for supporting one or more samples 310, e.g., a substrate having a pre-defined structure such as structure 100.

CNT growth can be performed using different carbon-containing precursors. The inventors have demonstrated CNT growth using CVD with ethanol and carbon monoxide (CO), respectively, as the precursor. Catalytic growth is obtained with a relatively thick catalytic layer of Co, e.g., from about 20 nm to about 60 nm, at temperatures ranging from about 750 to about 850° C. Argon (Ar) is used as a carrier gas in both cases, although in general, other inert gases such as He or N₂, may also be used.

In the case of CO, the gas is introduced into the quartz tube 302 via the inlet 304 at a flow rate from about 100 standard cubic centimeters per minute (sccm) to about 900 sccm at a total pressure around 1 atmosphere. Enhanced CNT growth, e.g., higher yield, has been shown with the addition of hydrogen (H₂) to CO, e.g., Bladh et al., Appl. Phys. A70, 317-322 (2000) and Zheng et al., Nano Lett. vol.2, 895-898 (2002). Thus, in one embodiment, a mixture of H₂ and CO is used, with a H₂ flow rate of less than about 100 sccm and a CO flow rate of about 600 sccm.

Different methods may be used to introduce ethanol into the quartz tube 302. For example, Ar (100-300 sccm) may be passed through a bubbler (not shown) containing ethanol, with the dilute mixture containing ethanol at a total pressure ranging from about 2 Ton to about 1 atm. In one embodiment, the total pressure is about 2 to about 6 Torr. Alternatively, pure ethanol may also be used, in which case, it can be maintained at a pressure from about 2 to about 6 Torr during the CVD process. After CNT growth, e.g., which may last from about 10 to about 20 minutes, the sample can be cooled down inside the quartz tube 302 under inert atmosphere.

The growth of CNT (e.g., the structure and properties of CNTs) depends on several factors, including the pressure, concentration and flow rate of the carbon-containing precursor. When ethanol precursor is used, higher ethanol concentrations, or ethanol pressures (when pure ethanol is used), tend to favor formation of multi-walled CNTs (MWCNT), while formation of single-walled CNTs (SWCNT) is favored by lower precursor concentrations or pressures. When CO is used as the precursor, a higher H₂:CO flow ratio, e.g., higher than about 100 sccm of H₂ with about 600 sccm of CO, tend to result in the formation of MWCNTs. Conditions that favor MWCNTs also result in the formation of intertwined nanotubes or randomly grown nanotube bridges or connections.

Unlike other CVD studies, which typically use a catalytic layer with a thickness of less than about 1 nm, embodiments of the present invention allow CNT growth with the use of a relatively thick Co catalytic layer. Analyses of the CVD samples by scanning electron microscopy and energy dispersive X-ray (EDX) suggest that, in the proximity of a tip, at least a portion of the Co catalytic layer interacts with the carbon-containing precursor, resulting in the formation of a modified layer. This modified layer contains at least cobalt and carbon. A portion of this modified layer may be partially detached from the underlying material, e.g., the catalytic or metallic layer. The modified layer may also include the formation of islands, e.g., aggregates of catalytic materials, which serve as catalytic points for CNT growth.

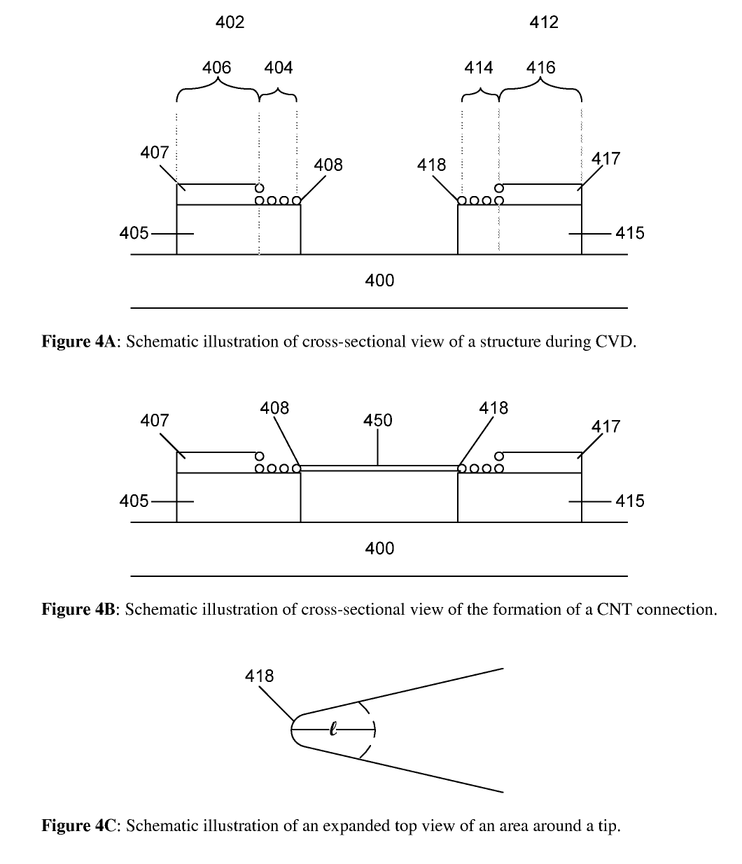

FIG. 4A is a schematic cross-sectional view of a structure illustrating the formation of a modified layer and islands during CVD. The structure has a substrate 400 over which layers similar to that of FIG. 1 may be formed, e.g., with conductive members 402, 412 having respective pads 406, 416, tapered portions 404, 414 with tips 408, 418. The conductive members 402, 412 include respective metal layers 405, 415 formed over the substrate 400. As shown in FIG. 4A, at least a portion of each catalytic layer above the metal layers 405, 415 is modified during CVD, resulting in the formation of modified layers 407, 417. Portions of the modified layers 407, 417 may detach from the underlying materials, and may also result in island formation near the tips 408, 418.

FIG. 4B is a schematic cross-sectional view of the structure of FIG. 4B, showing the formation of a nanotube bridge 450, or connection across the tips 408, 418. Specifically, one end of the nanotube bridge 450 is attached to the tip 408, while the other end of the nanotube bridge 450 is attached to the tip 418. It is understood that, when reference is made to a nanotube as being attached to a tip, it generally includes a situation where the CNT attachment point is within a proximate area surrounding the tip. For example, the proximate area may be defined by a distance (1) of less than about 200 nm from the tip. This is illustrated in FIG. 4C, which is an expanded top view around the tip 418, showing the proximate area having a distance 1 from the tip.

It is believed that if the catalytic layer is too thin, it tends to remain intact at high temperatures, e.g., without forming islands, or it may form a composite with the underlying metallic layer (e.g., Ti). On the other hand, if the catalytic layer is too thick, it is easily broken into islands, and yet, may not result in optimally-sized seeds for CNT growth. According to another embodiment of the present invention, H₂ is used before or during the bridge formation to modify the catalytic growth. The effect on the catalytic growth is believed to result from a partial reaction of H₂ that reduces cobalt oxide (formed on the cobalt surface) to pure cobalt.

It is believed that the tip structure of the present invention facilitates the intra-connect growth by enhancing the optimal thermal and electrical growth conditions in the vicinity of the tip, which allows the catalytic layer to be broken into optimal dimensions for a catalytic seed. The formation of the optimal catalytic seed near the tip allows the position of the intra-connect to be pre-defined in the proximity of the respective tips. For example, a nanotube connection may be formed between the two electrodes with each end of the nanotube being within a distance of about 200 nm from the respective tip.

In general, there may be more than one bridge grown between the areas surrounding the tips. However, with proper choice of precursor and growth conditions, such as precursor concentration, pressure, flow rate, and so on, one can achieve controlled formation of a single CNT bridge, including SWCNT.

Furthermore, selective growth of CNT connections can also be achieved between given conductive members. For example, using lithographic techniques, regions of a structure may be masked off with a suitable material layer, e.g., an oxide, to prevent CNT growth. After CNT growth is completed for the unmasked region, the oxide mask may be removed by etching, e.g., with HF, without substantial damage to the CNT connections.

The inventors have demonstrated the formation of CNT bridges, including SWCNT and MWCNT, using CVD under various process conditions. In general, CNT growth depends both on the size of the catalytic seed and the growth temperature. The size of the catalytic seed is affected by the thickness of the catalytic layer (e.g., Co layer). A proper choice of growth temperature is needed to achieve controlled CNT growth without giving rise to amorphous carbon or and uncontrolled growth such as bent or curly bridges. Under the proper conditions, the as-grown CNT forms a continuous electrical connection between the tips, with measurable electrical conductivity without any need for further processing.

In one example, well-aligned SWCNT bridges have been formed between two tips using ethanol precursor at a pressure of about 2 torr at a temperature of about 800° C. At a pressure of about 1 atm., however, a MWCNT bridge is formed. Electrical characterization of the CNT bridges shows that, although the resistance between the tips with the MWCNT bridge is larger than the value for the SWCNT bridge by two orders of magnitude, both CNT connections have similar current densities of about 10⁵ A/cm² (at a bias voltage of about 1 V) because of the larger diameter of the MWCNT. The length of the CNT intra-connect is about 1 μm, which is within the ballistic regime. This means that most of the resistance is a result of the metal-CNT contacts. The resistance value or the shape of the I-V curve for these CNT connections is not affected by switching the polarity between the tips, which means that the contact barriers are symmetrical and relatively small.

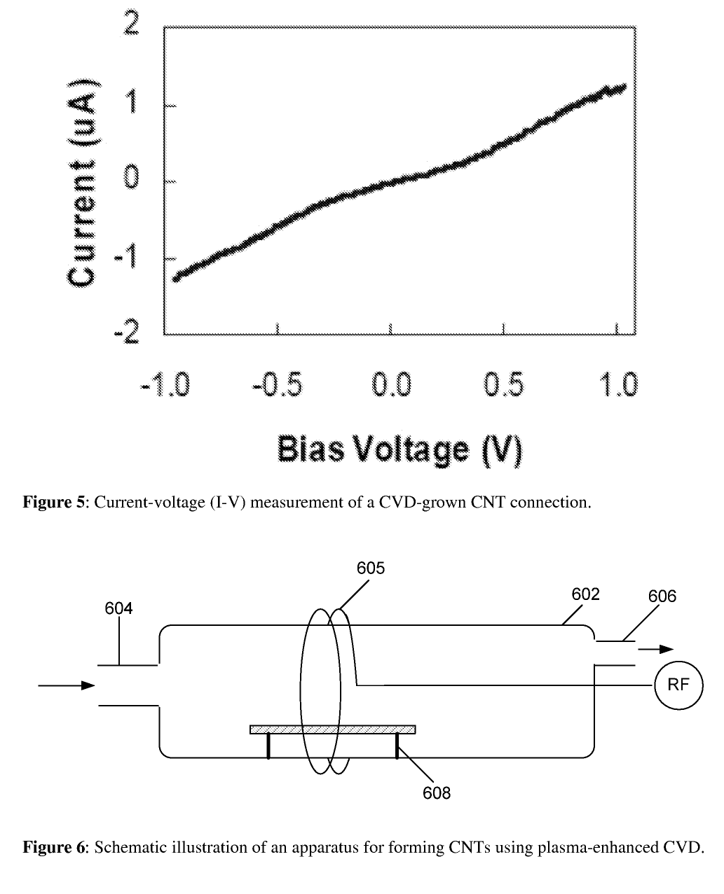

FIG. 5 shows a current-voltage (I-V) measurement of a CVD-grown CNT bridge with ethanol precursor at a pressure of about 2 torr and a temperature of about 800° C. For this sample, the catalytic Co layer has a thickness of about 20 nm and the Ti layer has a thickness of about 5 nm, respectively. The CNT is capable of carrying a current of about 1 μA and a higher current results in burning the CNT connection. Assuming a CNT bundle with a diameter of about 5 nm, one can deduced a corresponding current density of about 10⁶ A/cm².

In another example, a CNT bridge is formed between two tips by CVD using CO as the precursor at a flow rate of about 300 sccm at a temperature of about 780° C. In some situation, the as-grown CNT connection may be initially bent, but becomes a straight bridge connection upon applying a voltage bias of about 1 V across the tips. Such an approach is particularly useful in applications where it is desirable to have a known or controllable length for the conductive path, e.g., sensors and optoelectronic switches. Since the sensitivity of a sensor often depends on the length of the CNT bridge, the ability to form sensors with straight bridges or known CNT lengths can greatly facilitate the sensing applications. This approach of forming straight bridges can be applied to as-grown CNT connections, or to CNT connections coated with an electrically conductive polymer (which is discussed in a later section).

### Synthesis by PECVD

In another embodiment, plasma-enhanced CVD (PECVD) is used for growing the CNTs. In this case, an apparatus such as that in FIG. 3 may be modified for generating a radio-frequency (RF)-plasma, e.g., at about 13.6 MHz. FIG. 6 shows one example of an apparatus 600 suitable for CNT growth using PECVD. In one embodiment, a wire with a length of about 0.5 m, made of a high melting point and non-oxidizing metal (e.g., Ni or W) is used. The inductive antenna 605 is aligned axially with the quartz tube 602, and forms one or more loops on the outside of the tube 602, near the center of the tube.

In this example, the tube 602 has a diameter of about 1 inch. This configuration provides a RF field that is concentrated near the center of the tube 602, where the samples are located. This design is capable of providing RF power in access of about 50 W, which is sufficient to ionize the precursor mixtures of CO/H₂ and ethanol/Ar at pressures between about 0.1 to about 1 torr. For higher pressures, a Ti wire is preferred because of its stability in air.

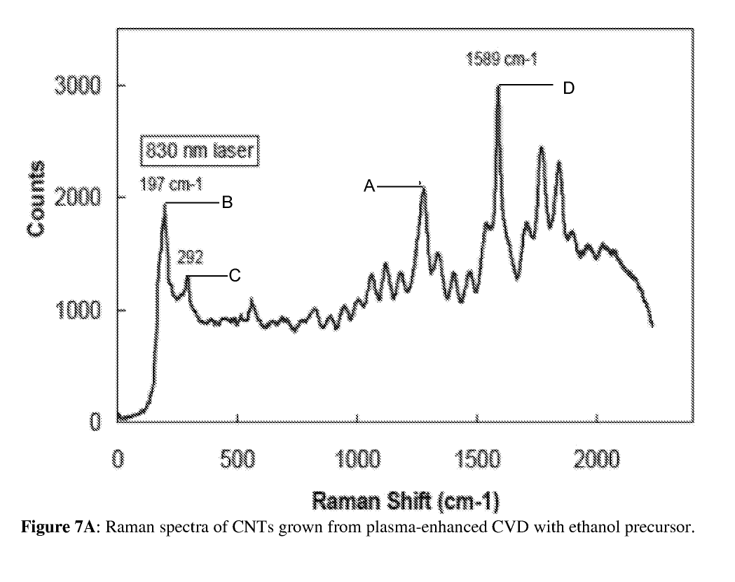

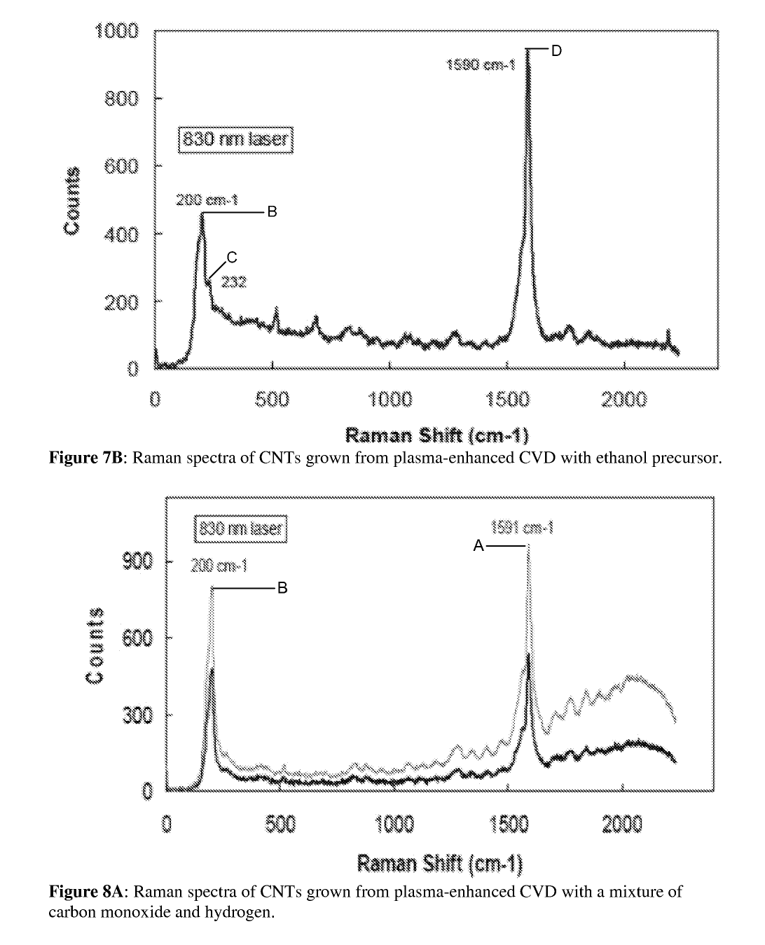

Growth of CNTs with PECVD has also been demonstrated with a substrate of opal at different conditions. In one example, SWCNT are grown with ethanol precursor at a temperature of about 620° C. and about 800° C., respectively, with ethanol/Ar at a pressure of about 140 mtorr and a RF power of about 50 W. FIG. 7A-B show two Raman spectra obtained for these SWCNT samples using a laser at 830 nm at 100 mW with a spot size of about 10 μm². FIG. 7A is the spectrum for the CNT grown at 620° C., showing a peak A at about 1350 cm⁻¹, which is attributable to disordered graphite such as amorphous carbon. Other peaks B, C and D, at about 197 cm⁻¹, 292 cm⁻¹ and about 1590 cm⁻¹, respectively, are associated with SWCNT.

FIG. 7B is a Raman spectrum for the CNT grown at 800° C., which shows two peaks B and C around 200 cm⁻¹ and 232 cm⁻¹, respectively, and very strong peak D at about 1590 cm⁻¹, all of which are associated with SWCNT. Unlike the spectrum in FIG. 7A, however, the signal at around 1350 cm⁻¹ is very weak, suggesting only a minimal amount of amorphous carbon and a weak CNT defect mode (e.g., a defect-free CNT connection).

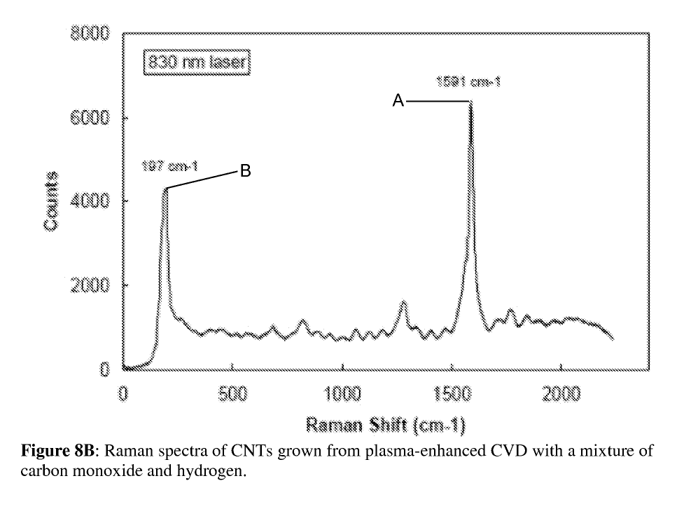

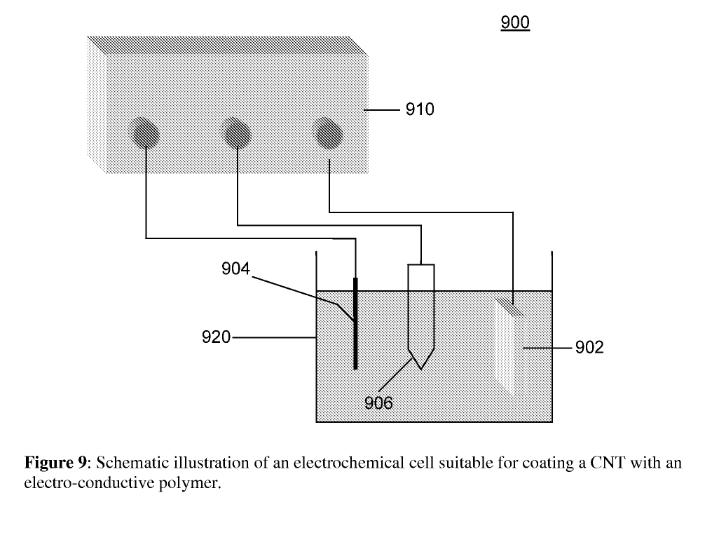

PECVD growth of CNTs have also been performed with a mixture of CO and H₂ at a total pressure between about 0.5 to about 2 torr with a CO:H₂ ratio varying from 1 to 2. FIG. 8A-B show the Raman spectra for two samples of SWCNT grown by PECVD with a mixture of CO and H₂ at 750° C. FIG. 8A corresponds to a CNT grown at a total pressure of about 2 torr, a ratio of CO:H₂ of 1:1, and a RF power of about 200 W. The two peaks correlate to two different samples taken from different locations, however they still show the same requisite peak values. FIG. 8B corresponds to a CNT grown at a total pressure of about 440 mtorr, a ratio of CO:H₂ of 7:4, and a RF power of about 105 W. Both spectra show the high and low frequency peaks around 1591 cm⁻¹ (peak A) and 200 cm⁻¹ (peak B) associated with SWCNT. The spectra are quite similar, and the extremely weak signal at around 1350 cm⁻¹ in FIG. 8A suggests a relatively pure CNT sample that is substantially free of amorphous carbon.

At a temperature range of about 600-900° C., it is found that the growth of SWCNT take place only in the presence of H₂. It is believed that H₂ may help in removing amorphous carbon during the PECVD process, thus avoiding potential catalyst poisoning that can otherwise terminate the CNT growth. The relatively high ratio of 15:1 between the peak A at around 1591 cm⁻¹ and the amorphous carbon signal in FIG. 8A is attributable to the relatively high degree of purity in the grown CNT.

After the CNT bridge or connection is formed between the tips, additional processing steps may be performed, as needed, to fabricate devices for various applications.

Electroplating of CNT Connection with ECP

According to another embodiment of the invention, the CNT bridge or intra-connect can also be further processed to provide at least one coating of an electrically conductive polymer (ECP). The resulting CNT-ECP intra-connect is found to provide enhanced electrical properties compared to the CNT connection without ECP. Alternatively, multiple coatings of different conductive polymeric materials may also be formed over the CNT bridge.

FIG. 9 shows an apparatus 900 that can be used for electro-polymerization, in which the CNT bridge is coated with an ECP. In this illustration, the apparatus 900 is a three compartment electrochemical cell 910, such as a 273 EG&G Princeton Applied Research Potentiostat/Galvanostat. The CNT intra-connect that is formed as previously described serves as a working electrode 902 in the electro-polymerization process. A platinum wire 904 and Ag/AgCl electrode 906 are used as counter electrode and reference electrode, respectively. The applied potentials are referenced against the Ag/AgNO₃ electrode, with a typical electroplating voltage being at about 0.8 V. Alternatively, electrochemical cell with a two electrode configuration may also be used.

In one example, the ECP to be coated onto the CNT is polypyrrole (PPy), which can be synthesized by electrochemical oxidation of pyrrole. An aqueous solution of about 0.5 M pyrrole and 0.5 M potassium chloride (KCl) (obtained from Sigma-Aldrich) is used without further purification. The solution containing pyrrole and KCl is put into the electrochemical cell 910, and a constant potential bias, e.g., about 0.8 V is applied across the working electrode 902 and the counter electrode 906 in order to deposit the PPy material onto the CNT. A deposition thickness of about 50-1000 nm may be obtained, depending on the duration time of plating. The deposition time may vary according to specific needs, but is typically around 30 seconds. In one embodiment, the ECP thickness is equal to or larger than about 80 nm.

Deposition of PPy occurs only on conductive surfaces, and is manifested as a black film, e.g., over the metal electrode area and the CNT bridge. After electrodeposition, the sample can be cleaned with deionized water and let dry out under an inert gas, e.g., nitrogen gas. Details relating to deposition of PPy can be found in Snook et al., “Studies of deposition of and charge storage in polypyrrole-chloride and polypyrrole-carbon nanotube composites with an electrochemical quartz crystal microbalance”, Journal of Electroanalytical Chemistry, vol. 568, 135-142 (2004).

Other electrically conductive polymers that are suitable for coating the CNT bridges include, for example, polycarbazole (PCZ), polythiophene, and TPAsTPBF20, among others. Polycarbazole, for example, can be polymerized in a solution containing 0.02 M carbazole monomer and 0.2 M TBABF₄ (tetrabutylammonium tetrafluoroborate) in acetonitrile and 20 mM carbazole in Acetonitrile (ACN), with a constant potential of about 1.1 V. Polythiophene can be synthesized by using a solution of 1 mM TPAsTPBF20 and 10 mM 2,2′:5′2″ terthiophene (Fluka) in 1,2-Dichloroethane (DCE), with a constant potential of about 1.1 V applied across the electrodes. TPAsTPBF20 can be made by mixing same amounts of lithium tetrakis-(pentafluorophenyl)-borate etherate (Boulder Scientific, at a purity higher than about 99% purity) in methanol and tetraphenyl-arsonium chloride hydrate (TPAsCl) (Fluka, at a purity level higher than about 95%) in de-ionized water.

Details for depositing these ECP by electro-polymerization can also be found in the following references: Diamant et al., “Electrochemical polymerization, optical and electrical characterizations of polycarbazole on single wall carbon nanotubes”, Synthetic Metals, vol. 151, 202-207 (2005); Vignali et al., “Characterization of doping and electropolymerization of free standing films of polyterthiophene”, Journal of Electroanalytical Chemistry, vol. 592, 37-45 (2006); and Vignali et al., “Electropolymerized polythiophene layer extracted from the interface between two immiscible electrolyte solutions: Current-time analysis”, Journal of Electroanalytical Chemistry, vol. 591, 59-68 (2006).

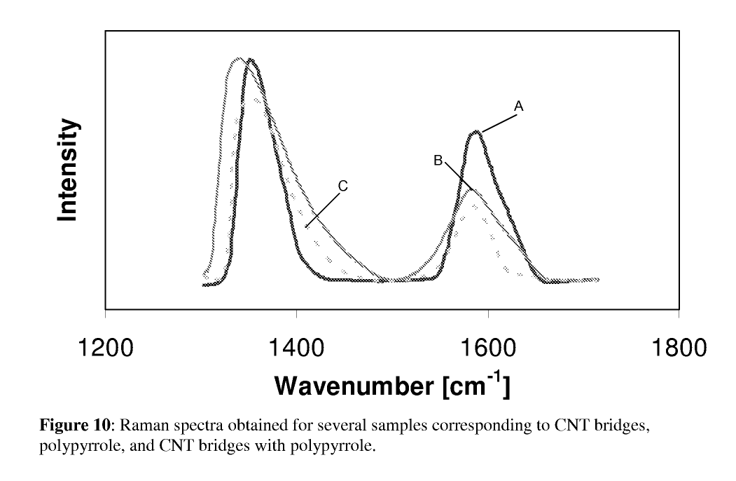

FIG. 10 shows the Raman spectra obtained for several samples corresponding to CNT bridges only (curve A), PPy only (curve C) and CNT bridges coated with PPy (curve B). The spectra are obtained by focusing an Ar ion laser at 514.5 nm between the tips. Analysis of the data allows the identification of peaks associated with MWCNT (1350, 1585 and 1619 cm⁻¹) and PPy (1330, 1370 and 1584 cm⁻¹), respectively. In these samples, low-frequency signals are absent in the Raman spectra, suggesting the formation of MWCNT bridges (as opposed to SWCNT).

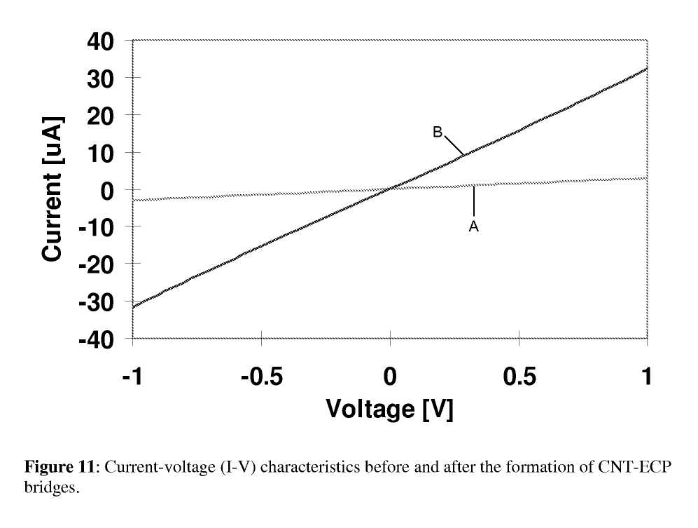

FIG. 11 shows the current-voltage (I-V) characteristics before and after the formation of CNT-PPy bridges. As shown by line A, the conductivity for CNT-only bridges, i.e., CNT before coating with Ppy, is on the order of 10⁻⁶ Ampere at 1 volt. For CNT-PPy, however, the conductivity increases by over 10 times, to about 10⁻⁵ Ampere, as shown by line B.

In addition, investigations of the optical properties of the CNT-PPy connection suggest that, while the CNT connection (without PPy) shows a small photo-conductance effect, i.e., conductance increases upon exposure to white light (about 150 mW/cm² at wavelengthss longer than 400 nm), there is a decrease in conductance upon exposure to UV light (about 4 mW/cm² at a wavelength of about 355 nm).

The CNT-PPy connection, on the other hand, shows a relatively small photo-conductance upon exposure to white light, which is attributable to the CNT component, since PPy is not sensitive to white light. However, upon exposing teh CNT-PPy to UV light, there is a significant decrease in conductance. In many cases, the current through the CNT-PPy connection decreases to zero, with the connection becoming essentially open in less than a minute. When the UV light is removed, the conductance of the CNT-PPy connnection recovers, within a minute, to its value prior to UV exposure. This wavelength dependent property may be used in fabricating a radiation sensor.

### Nanotube-Based Devices

The CNT connections can be used, with or without coating by PPy or other electrically conductive polymers, in the fabrication of a variety of nanotube-based devices, including transistors, optoelectronic switches, various sensors such as chemical, bio-sensors, or radiation sensors, among others. If a conductive polymer-coated CNT connection is used in a device, the CNT may either be semiconducting or metallic.

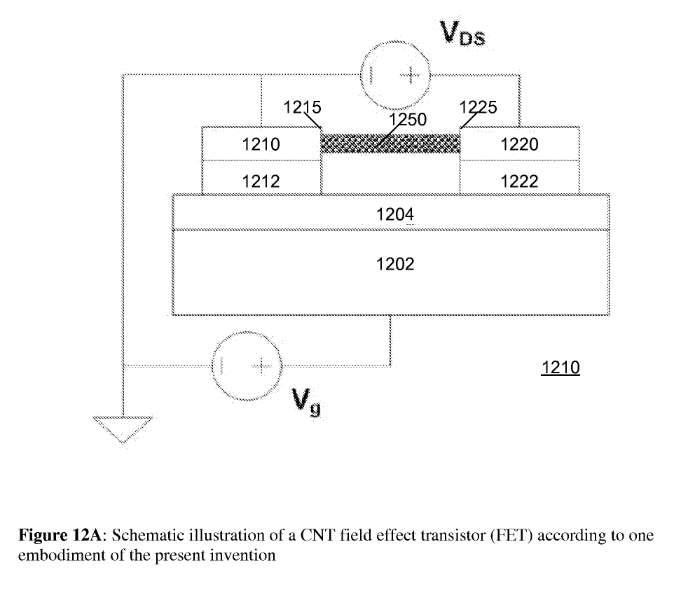

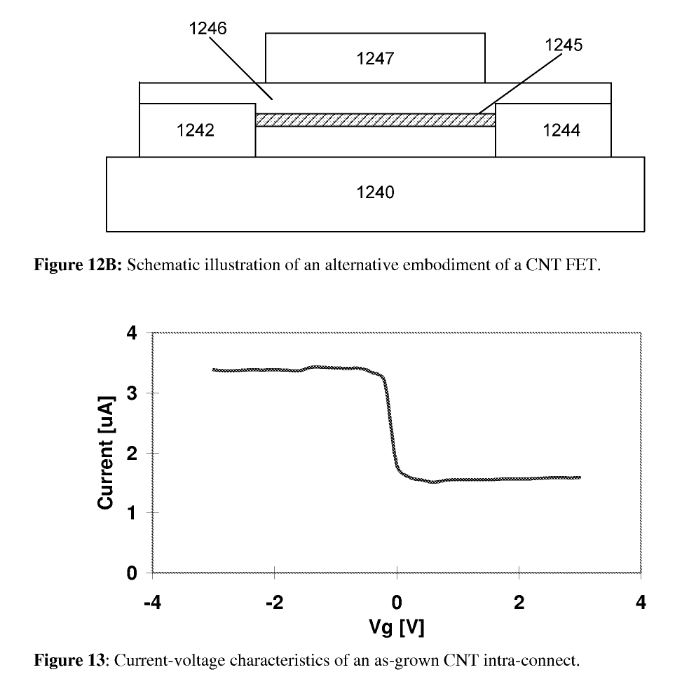

FIG. 12A is a schematic illustration of a CNT field effect transistor (FET) according to one embodiment of the present invention. The FET 1200 includes a back gate electrode 1202, which may be made through an ohmic contact to the silicon substrate (e.g., typical thickness of about 500 μm). A gate dielectric layer 1204, e.g., oxide or polymer such as polyimide, with a thickness of about 2 nm to about 20 nm, is formed over the gate 1202.

Each of the source and drain electrodes, 1210 and 1220, is made of a catalytic material, e.g., Co, formed over a bottom adhesion layer 1212, 1222. Other materials, e.g., iron (Fe) or nickel (Ni), may also be used as catalytic material. The conductive electrodes 1210 and 1220, which include at least Co, may generally have a thickness between about 30 nm to about 1500 nm. These electrodes may also contain either gold, aluminum or copper on top of the cobalt. The adhesion layer may have a thickness between about 1 nm to about 30 nm, and may be made of Ti, chromium or palladium.

Similar to the structure discussed in connection with FIG. 1, the adhesion layers 1212, 1222 and the conductive layers of the source and drain electrodes 1210, 1220 are patterned to provide respective tapered portions that include tips 1215 and 1225. A CNT 1250 is then formed between the two tips 1215 and 1225, for example, using techniques such as thermal CVD or PECVD. The CNT 1250 serves as the channel of the FET 1200.

In one example, a CNT FET has been fabricated with a CNT channel formed by CVD growth using CO precursor at a temperature of about 750° C. No post-growth processing is needed to produce the functioning FET. As-grown CNT are naturally p-type and require negative gate voltage to operate in a switched mode FET configuration.

FIG. 12B shows an alternative embodiment of a FET with a front gate configuration. In this case, the source and drain electrodes 1242, 1244 (each of which includes a conductive layer such as Ti and a catalytic layer such as Co) are formed over a suitable substrate 1240. A gate dielectric 1246, e.g., an oxide or polymer such as polyimide, with a thickness of about 2 nm to about 20 nm, is formed over at least the CNT channel 1245. A gate electrode 1247, e.g., with a typical thickness of about 1 μm, is then formed over the gate dielectric 1246.

FIGS. 13-15 show the current-voltage (I-V) characteristics of a FET before and after the coating of the CNT channel with PPy. In this example, the drain-source voltage, V_{ds} is fixed at 1 V, while the gate voltage is varied between −3 V to 3 V. FIG. 13 shows the I-V_{g} characteristic of one as-grown CNT channel. When the gate voltage is positive, the current is in the micro-ampere range. The current abruptly increases when a negative gate voltage is applied. This step-like characteristic is typically observed for a CNT channel made of a single CNT bridge or a few CNT bridges (may be single- or multi-walled CNT), with each bridge having a diameter of about 20 nm or less. For a channel made of one or more relatively thick CNT ropes, e.g., each having a diameter of about 100 nm or more, the I-V curve will not exhibit this step-like behavior, but instead, will resemble a smooth curve.

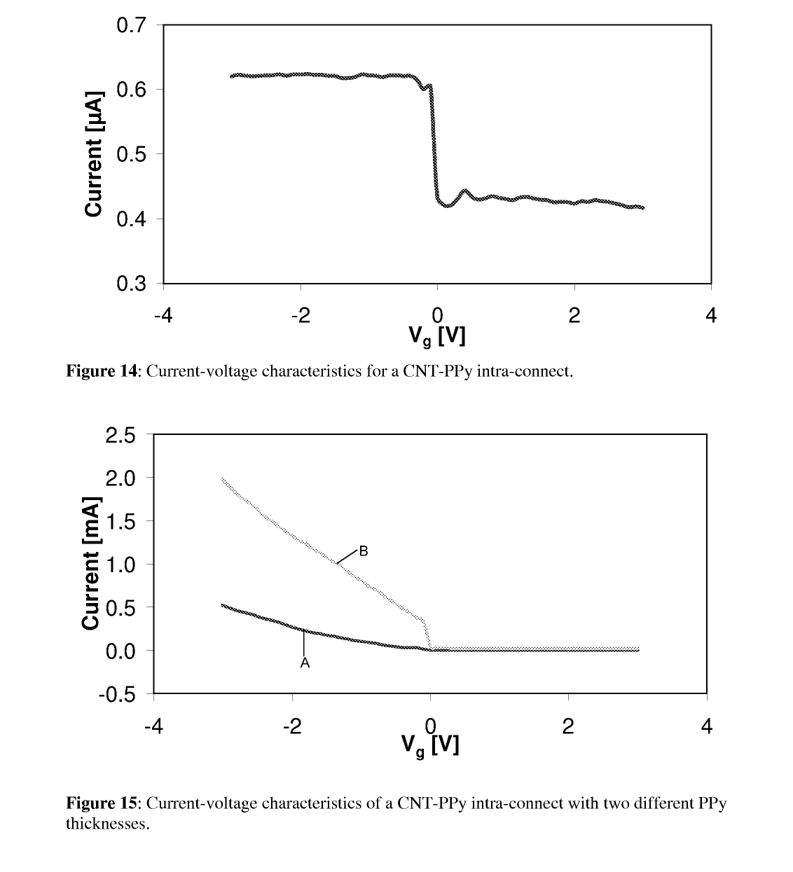

FIG. 14 shows the I-V_{g} measurements for the same CNT after it has been coated with PPy having a thickness of about 80 nm. The characteristics are similar to those of a CNT bridge, without ECP coating.

FIG. 15 shows the I-V_{g} measurements of CNT-PPy intra-connect with two different PPy thickness, 360 nm (curve A) and 580 nm (curve B), respectively. For both of the CNT-PPy, the current increases linearly as a function of the negative gate voltage. In the case of the CNT-PPy with the thicker polymeric coating (curve B), it is believed that the larger cross-section of the CNT-PPy bridge and electrodes results in a larger overall current compared to the CNT-PPy with a thinner polymeric coating.

As another example, a sensor, e.g., a biosensor, can also be fabricated by incorporating a CNT connection such as that described above. Such a device has a structure similar to that of a FET, except that the CNT connection is coated with an ECP that has been functionalized according to the sensing applications. Specifically, functional biological molecules may be mixed with a solution containing suitable precursors for forming the ECP. Electroplating of the CNT with such a solution will result in a CNT coated with functionalized ECP.

When a molecule (for which the sensor is designed for) binds to the functionalized CNT-ECP connection, it changes the electrical property of the device, e.g., the voltage at which the device is held, thus allowing the detection of the molecule. Details relating to the fabrication of biosensors can be found in Wanekaya et al., “Nanowire-based Electrochemical Biosensors”, Electroanalysis, vol. 18, 533-550 (2006), and the incorporation of oligonucleotide (ODN) into pyrrole (Py) moiety has been shown by Cheung et al., “Detection of single nucleotide polymorphisms by minisequencing on a polypyrrole DNA chip designed for medical diagnosis”, Laboratory Investigation vol. 86, 304-313 (2006). doi:10.1038/labinvest.3700387; published online 6 Feb. 2006. Both references are herein incorporated by reference in their entireties.

While the foregoing is directed to embodiments of the present invention, other and further embodiments of the invention may be devised without departing from the basic scope thereof, and the scope thereof is determined by the claims that follow.

1. A structure, comprising:
two conductive tapered members each having a tip with a radius of curvature less than about 20 nm; wherein the two tips are separated by a distance of less than about 1500 nm.

2. The structure of claim 1, wherein each tapered member comprises a region defined for forming a nanotube connection, and the region is defined by a distance of less than about 200 nm from each tip.

3. The structure of claim 1, wherein each of the two conductive tapered members further includes a first metal layer, the metal being selected from at least one of cobalt, iron and nickel.

4. The structure of claim 3, wherein each of the two conductive tapered members further includes a second metal layer, the metal being selected from at least one of titanium, chromium and palladium.

5. The structure of claim 4, wherein the first metal layer has a thickness between about 20 to about 60 nm, and the second metal layer has a thickness of less than about 30 nm.

6. The structure of claim 4, further comprising:
a carbon nanotube forming a connection between the two tips.

7. The method of claim 6, wherein the first metal layer is cobalt with a thickness of about 30 nm.

8. A method of forming a nanotube-based structure, comprising:
providing two conductive tapered members each having a tip;
forming a nanotube connection between the two tips.

9. The method of claim 8, wherein each of the two tips has a radius of curvature less than about 20 nm.

10. The method of claim 8, wherein the two conductive tapered members each comprises a first metal and a second metal, the first metal being selected from at least one of cobalt, iron and nickel, and the second metal being selected from at least one of titanium, chromium and palladium.

11. The method of claim 10, wherein the nanotube is a carbon nanotube, and the method further comprises:
forming the carbon nanotube from a carbon-containing precursor by chemical vapor deposition.

12. The method of claim 11, further comprising:
performing the chemical vapor deposition at a temperature of about 750° C. to about 800° C.

13. The method of claim 11, further comprising:
forming the carbon nanotube in a quartz tube by providing an inductive antenna around the tube to form a plasma for plasma enhanced chemical vapor deposition.

14. The method of claim 10, wherein the first metal layer is cobalt with a thickness of about 30 nm.

15. A nanotube-based structure, comprising:
a first conductive tapered member comprising a first tip;
a second conductive tapered member comprising a second tip;
a nanotube having a first end attached to the first tip and a second end attached to the second tip;
wherein the first and second tips each has a radius of curvature of less than about 20 nm.

16. The nanotube-based structure of 15, wherein the nanotube is a carbon nanotube.

17. The nanotube-based structure of 16, wherein the carbon nanotube further comprises a coating of an electrically conductive polymer having a thickness at least equal to about 80 nm.

18. The structure of claim 15, wherein the first and second conductive tapered members each includes a cobalt layer with a thickness of about 30 nm.

19. A nanotube-based device, comprising:
a first conductive tapered member comprising a first tip;
a second conductive tapered member comprising a second tip;
a nanotube connection between the first and second tips;
a dielectric; and
a conductive layer separated from the nanotube connection by the dielectric.

20. The device of claim 19, wherein the device is a field effect transistor (FET), the first conductive tapered member is a source electrode, and the second conductive tapered member is a drain electrode.

21. The nanotube-based device of claim 19, wherein each of the two tips has a radius of curvature less than about 20 nm.

22. The device of claim 19, wherein the nanotube further includes at least one coating of electrically conductive polymer.

23. The device of claim 22, wherein the at least one coating of electrically conductive polymer further comprises at least one functional biological molecule.

24. The nanotube-based device of claim 20, wherein the source and drain electrodes each includes a cobalt layer with a thickness of about 30 nm.
